(19) United States
(12) Patent Application Publication
(10) Pub. No.: US 2009/0123870 A1
(43) Pub. Date: May 14, 2009

(54) METHOD OF AND SYSTEM FOR ELECTON BEAM LITHOGRAPHY OF MICRO-PATTERN AND DISC SUBSTRATE HAVING MICRO-PATTERN TO BE TRANSFERRED

(75) Inventors: Toshihiro USA, Odawara-shi (JP); Kazunori Komatsu, Odawara-shi (JP)

Correspondence Address: YOUNG & THOMPSON, 209 Madison Street, Suite 500, ALEXANDRIA, VA, 22314, US

(73) Assignee: FUJIFILM CORPORATION, TOKYO (JP)

(21) Appl. No.: 12/269,912

(22) Filed: Nov. 13, 2008

(30) Foreign Application Priority Data
Nov. 13, 2007 (JP) 2007-293975

(51) Int. Cl. G03F 7/20; G11B 5/82; G21K 5/04

(52) U.S. Cl. 430/296; 360/135; 250/492.3

(57) ABSTRACT

An electron beam lithographic method and system for forming a micro-pattern, including servo patterns each of which comprises a plurality of recessed servo elements in a track and groove patterns each of which comprises an inter-track groove extending along the track and to be formed on a discrete track medium, on the a resist coated disc substrate by scanning the resist-coated surface with an electron beam during rotation of the disc substrate. A sequential process of the electron beam lithography comprises the steps of forming the servo elements as an latent image in the resist-coated surface with an electron beam having an irradiation spot diameter smaller than a width of the servo element during rotation of the disc substrate and, subsequently, forming the inter-track grooves in a latent image in the resist-coated surface by intermittently scanning the resist-coated surface in a direction perpendicular to a track direction at regular intervals during rotation of the disc substrate so as thereby to form a continuous row of groove elements into which the inter-track groove is divided.

### BACKGROUND OF THE INVENTION

1. Field of the Invention

The present invention relates to a method and a system for electron beam lithography and, more specifically, to an electron beam lithographic method for depicting an image of a micro-pattern on a resist-coated substrate which is used as an imprint mold for producing a discrete track recording medium and an electron beam lithographic system for performing the electron beam lithographic method.

2. Description of Related Art

As a method of forming a micro-pattern such as a servo pattern on a magnetic recording medium, there has been known an electron beam lithographic method disclosed in, for example, U.S. Pat. No. 7,026,098. In the electron beam lithographic method, a resist-coated disc substrate, which is used for manufacturing of discrete track recording mediums, is scanned with an electron beam according to a micro-pattern to be formed on the discrete track recording medium while rotating. Specifically, rectangular- or parallelogram-shaped servo elements extending in a direction perpendicular to a track, i.e. a radial direction, which form a servo pattern are daubed with the electron beam oscillating at a high frequency in a circumferential direction while deflected in the radial direction during rotation of the disc substrate. EP 1347450A2 discloses another electron beam lithographic method. This electron beam lithographic method includes a step of adjusting an amplitude of oscillation of an electron beam following rotation of a disc substrate while oscillating it in a radial direction at a high frequency during depicting pits, fixed in width in the radial direction and different in length in the track direction, of a pit train.

There have been known on-off lithographic methods. In such an on-off lithographic method, a resist-coated disc substrate or an electron beam irradiation equipment is relatively moved by a distance equal to an irradiation spot diameter of the electron beam every one revolution of the resist-coated disc substrate while turning on and off the electron beam according to a predetermined pattern.

A recent noteworthy development in high-density magnetic recording technique is directed to discrete track recording (DTR) and a discrete track medium (DTM). The discrete track medium is characterized in magnetically isolating adjacent data tracks from one another by patterned inter-track grooves or guard bands so as to reduce or almost eliminate magnetic interference between adjacent data tracks. However, it is difficult for the prior art electron beam lithographic methods to depict accurately a given width of an inter-track groove or guard band. That is, in the electron beam lithographic method disclosed in U.S. Pat. No. 7,026,098, although it is secured to depict a micro-pattern such as a servo pattern of the discrete track medium on the disc substrate with exactly the same properties as specified in the description, when depicting patterned inter-track grooves (an inter-tack groove pattern) of the discrete track medium on the disc substrate by a stationary electron beam subsequently to depiction of the servo pattern while rotating the disk substrate in a circumferential direction, the individual inter-track becomes excessively wide relative to a track width due to blurring of irradiation of the electron beam. This is because, in order that, when depicting the servo pattern, the electron beam is oscillated at a high frequency in the circumferential direction while scanning a specified area during a regular angle of rotation of the disk substrate, the intensity of the electron beam is set so high as to provide a specified dose of electron beam irradiation for the specified area of scanning and it is so hard to reduce the intensity of the electron beam upon a transition to depiction of the inter-track groove pattern from depiction of the servo pattern in terms of operating responsibility of an electron beam irradiation equipment.

The prior art electron beam lithographic method described in EP 1347450A2 is similar in the way of servo pattern lithography to the previous method and accompanied by the same problem that it is difficult to depict an inter-track groove having an accurate width because of an excessive irradiation dose. [0011]

In this instance, although the on-off lithographic method is suitable for depiction of an inter-track groove pattern, however, it needs a considerable time on depiction of the servo pattern and has such a problem that it is hardly performable for the electron beam to ensure on-off positions and radial positions for sufficiently precise depiction of a specified pattern.

It is therefore an object of the present invention to provide an electron beam lithographic method for performing accurate and high speed lithography of a micro-pattern including servo patterns and inter-track groove patterns on a imprint disc substrate for manufacturing discrete track mediums at a fixed irradiation dose of an electron beam and a system for performing the electron beam lithographic method.

It is another object of the present invention to provide a disc substrate with a micro-pattern of lands and grooves formed thereon.

### SUMMARY OF THE INVENTION

One aspect of the present invention relates to an electron beam lithographic method for forming an image of a micro-pattern on a resist-coated surface of a disc substrate by scanning the resist-coated surface of said disc substrate with an electron beam during rotation of the disc substrate. The micro-pattern, which is desirably to be topographically formed in each of concentric tracks of a discrete track medium, comprises a servo pattern which is configured by a plurality of recessed servo elements having specified regular widths in a direction of the track and a groove pattern which is configured by an inter-track groove extending along the track for magnetically isolating adjacent tracks from each other.

The electron beam lithographic method comprises the step of forming an image of said servo elements with an electron beam having an irradiation spot diameter smaller than said width of said servo element on sad resist-coated surface of said disc substrate during rotation of said disc substrate in one rotative direction, and the step of depicting, subsequently to depiction of the servo elements, the inter-track groove by linearly scanning the resist-coated surface of the disc substrate in a direction perpendicular to a radial direction of the disc substrate at regular intervals during rotation of the disc substrate so as thereby to depict a continuous row of groove elements into which the inter-track groove is divided. The electron beam may be deflected in the radial direction while oscillated at a specified frequency in a direction perpendicular to the radial direction so as to daub a shape of each of the servo elements during rotation of the disc substrate, thereby depicting the individual servo elements on the resist-coated surface of the disc substrate. Further, the electron beam may be intermittently deflected in a direction perpendicular to the radial direction and opposite to the rotative direction of the disc substrate during the rotation of the disc substrate so as to daub lines having lengths of the individual groove elements, thereby depicting a continuous inter-track groove on the resist-coated surface of the disc substrate. The electron beam lithographic method may further include the step of providing an encoder pulse for enabling irradiation of the electron beam to the resist-coated surface of the disc substrate immediately before image formation of each the groove element.

Another aspect of the present invention relates to an electron beam lithographic system for performing the electron beam lithographic method. Specifically, the electron beam lithographic system comprises a signal output unit for storing lithographic data representing an image of the micro-pattern and providing signals corresponding to the lithographic data and an electron beam lithographic apparatus operative according to the signals to perform the step of depicting the servo elements with an electron beam having an irradiation spot diameter smaller than the width of the servo element on the resist-coated surface of the disc substrate during rotation of the disc substrate in one rotative direction and depicting, subsequently to depiction of the servo elements, the inter-track groove by linearly scanning the resist-coated surface of the disc substrate in a direction perpendicular to the radial direction of the disc substrate at regular intervals during the rotation of the disc substrate so as to depict a continuous row of groove elements into which the inter-track groove is divided. The electron beam lithographic apparatus may comprise a rotating stage for bearing the disc substrate thereon; drive means for rotating the rotating stage in one rotative direction and linearly moving the rotating stage in a direction perpendicular to the rotative direction; an electron gun for emitting an electron beam; deflection and oscillation means for deflecting the electron beam in the radial direction of the disc substrate put on the rotating stage and in a direction perpendicular to the radial direction of the disc substrate and opposite to the rotative direction of the rotating stage and causing a high speed oscillation of the electron beam in a direction perpendicular to the radial direction at a fixed amplitude; blanking means for blanking irradiation of the electron beam onto the resist-coated surface of the disc substrate after image formation of each the servo element and each the groove element; and a controller for controlling coordinated operation of the drive means, the electron gun, the deflection and oscillation means and the blanking means so as to depict the micro-pattern according to the signals corresponding to the lithographic data provided by the signal output unit.

A further aspect of the present invention relates to a disc substrate bearing a micro-pattern in a topographical configuration which is used, e.g. as an imprint mold to transfer the micro-pattern onto a discrete track medium. The topographical micro-pattern of the disc substrate is formed by developing and etching the resist-coated surface of the disc substrate with the micro-pattern formed as a latent image therein by the electron beam lithographic method of the invention. In this instance, the imprint mold, which is one of master discs called stumper used for manufacturing discrete track mediums, is pressed against a resin layer to form a mask pattern for transferring the micro-pattern to a magnetic disc medium.

According to the electron beam lithographic method of the invention, in depicting a micro-pattern comprising servo patterns comprising servo elements having widths in a track direction greater than an irradiation spot diameter of the electron beam and inter-track groove patterns comprising groove elements extending adjacent tracks for isolation of adjacent tracks, the groove pattern is depicted, subsequent to depiction of the servo pattern, by linearly scanning the resist-coated surface of the disc substrate in a direction perpendicular to the radial direction of the disc substrate at regular intervals during rotation of the disc substrate so as thereby to constitute of a continuous row of groove elements into which an inter-track groove is divided. This sequential process facilitates depiction of the servo pattern and the groove pattern with a uniform irradiation does of electron beam for each track during one revolution of the disc substrate and, in consequence, enables to depict a micro-pattern comprising the servo-patterns and the groove patterns with high accuracy at a high speed. The electron beam lithographic method realizes efficient depiction of the micro pattern in a shortened time.

Since a shape of the servo element is daubed by deflecting the electron beam in the radial direction while oscillating it in a direction perpendicular to the radial direction at a high frequency during rotation of the disc substrate so as thereby to depict the servo element on the resist-coated surface of the disc substrate, high speed, precise depiction of the servo patterns in one track is performed during one revolution of the disc substrate. In addition, since line segments of the individual groove elements are daubed by intermittently deflecting the electron beam in a direction perpendicular to the radial direction and opposite to the rotative direction of the disc substrate during rotation of the disc substrate so as thereby to depict a continuous row of groove elements as an inter-track groove on the resist-coated surface of the disc substrate, the inter-track groove is depicted in a specified width without an occurrence of an excessive irradiation dose of electron beam. Furthermore, depiction of the groove element initiated and terminated on the basis of encoder pulses improves the accuracy of formative position of the micro-pattern, in particular, the groove pattern and, in consequence, provides precise formation of the micro-pattern allover the resist-coated surface of the disc substrate.

According to the electron beam lithographic system for performing the electron beam lithographic method which comprises a signal output unit for storing lithographic data representing the micro-pattern and providing signals corresponding to the lithographic data and an electron beam lithographic apparatus for performing scanning according to the lithographic data signals, the micro-pattern comprising the servo-patterns and the groove patterns is depicted with high accuracy at a high speed. Therefore, the electron beam lithographic system realizes efficient depiction of the micro pattern in a shortened time. In particular, the electron beam lithographic system is so configured that the electron beam lithographic apparatus comprises a rotating stage for bearing the disc substrate thereon, drive means for rotating the rotating stage in one rotative direction and linearly shifting a position of the rotating stage in a direction perpendicular to the rotative direction, an electron gun for emitting an electron beam, deflection and oscillation means for deflecting the electron beam in the radial direction of the disc substrate put on the rotating stage and in a direction perpendicular to the radial direction of the disc substrate and opposite to the rotative direction of the rotating stage while causing a high speed oscillation of the electron beam in a direction perpendicular to the radial direction at a fixed amplitude, and blanking means for blanking irradiation of the electron beam onto the resist-coated surface of the disc substrate after depiction of each servo element and each groove element. These component devices or means, i.e. the drive means, the electron gun, the deflection and oscillation means, and the blanking means, are controlled by the controller according to the lithographic data signals provided by the signal output unit so as to perform coordinated operation for depiction of the micro-pattern.

According to the disc substrate bearing a micro-pattern in a topographical configuration which is used, e.g. as an imprint mold, to transfer the micro-pattern onto a discrete track medium, the topographical micro-pattern is provided through the process steps of forming a latent image of the micro-pattern in a resist layer of the disc substrate by the electron beam lithographic method, developing and etching the resist layer and then etching the disc substrate through a patterned resist layer. The formation of the micro-pattern on the surface of the disc substrate is precise and easy. In particular, in the case of using the disc substrate having a micro-patterned surface as an imprint mold, blanket transfer of the micro-pattern to a magnetic recording medium is realized by pressing the imprint mold against a resin layer provided as a mask on the magnetic recording medium. This facilitates manufacturing of discrete track mediums having excellent recording/reproducing characteristics.

### BRIEF DESCRIPTION OF THE DRAWINGS

The foregoing and other objects and features of the present invention will be clearly understood from the following detailed description when reading with reference to the accompanying drawings wherein same or similar parts or structures are denoted by the same reference numerals throughout the drawings, and in which:

FIG. 1 illustrates, in schematic, simplified view, a micro-pattern of a discrete track medium which is depicted on a base substrate by an electron beam lithographic method of the present invention;

FIG. 2 illustrates an enlarged part of the micro-pattern;

FIGS. 3A to 3F) illustrate, in chart, details of electron beam control signals for implementing an electron beam lithographic method according to an embodiment of the present invention;

FIG. 4A illustrates, in schematic, simplified side view, an electron beam lithographic system according to an embodiment of the present invention; and

FIG. 4B illustrates, in schematic, simplified plane view, an electron beam lithographic apparatus; and

FIG. 5 illustrates, in schematic, simplified cross-sectional view, a process step for transferring a micro-pattern of the imprint mold to a slave substrate as a discrete track disc.

### DETAILED DESCRIPTION OF THE PREFERRED EMBODIMENTS

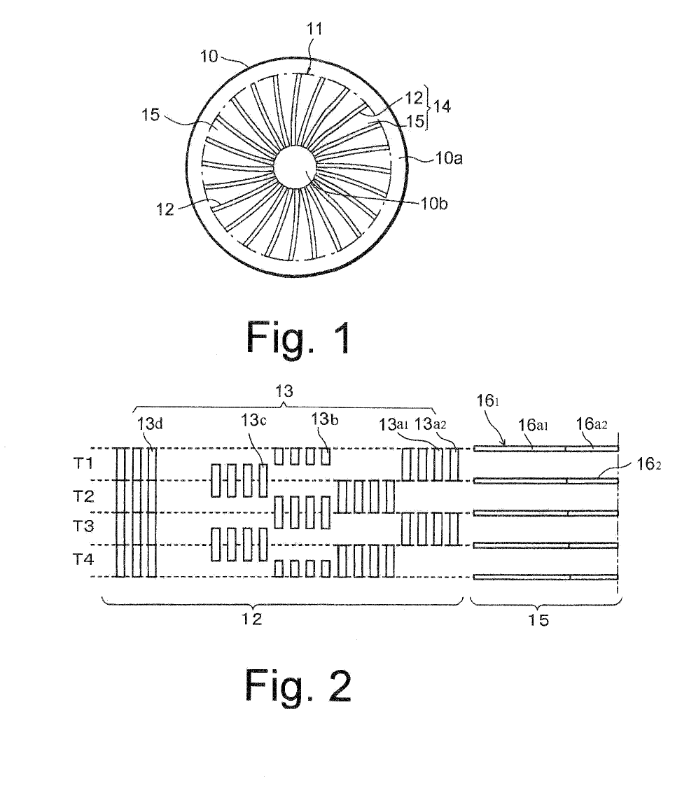

Referring to the drawings in detail and, in particular, to FIG. 1 schematically illustrating a micro-pattern of a discrete track medium which is formed on a disc-shaped base substrate (which is hereinafter simply referred to as a disc substrate) 10 by an electron beam lithographic method, and FIG. 2 illustrating, in enlarged and extended view, a part of the micro-pattern. As shown, the micro-pattern in the form of elevations. As is well known in the art, the discrete track magnetic recording medium has a plurality of sectors divided at regular angles in a circumferential or track direction. The individual sector comprises a servo area in which servo patterns are formed in a cluster in a great number of concentric tracks, respectively, and a data area in which groove patterns are formed in a cluster along concentric tracks, respectively.

The following description is directed to a micro-pattern of a cluster of servo patterns and a cluster of groove patterns included in one sector depicted as a latent image in a resist-coated surface of the disc substrate 10 by the electron beam lithographic method of the present invention.

As shown in FIG. 1, the disc substrate 10 has a positive type of resist layer 11 coated on a top surface thereof, excepting an outer periphery annular zone 10a and a center circular zone 10b, on which a latent image of the micro-pattern is formed by the electron beam lithographic method. The disc substrate 10 is translucent and preferably made from, for example, silicon, glass or quartz. The resist layer 11 of the disc substrate 10 is divided into a plurality of sectors 14 at regular angles in a circumferential or track direction. The individual sector 14 includes a servo area 12 and a data area 15 both of which extend and curve radially between the outer periphery annular zone 10a and the center circular zone 10b.

Referring to FIG. 2 showing a part of the sector 14 in detail, the sector 14 includes a great number of concentric tracks (only four tacks T1˜T4 are shown) each of which has the data area 15 including a groove pattern 16 and the servo area 12 including a servo pattern 13. The groove pattern 16 comprises an inter-track groove 16₁ divided into a plurality of very thin groove elements 16a1˜16an at regular angles in the track direction so as to form a continuous row of the groove elements 16a1˜16an along, e.g., the track T1. The servo pattern 13 comprises a plurality of rectangular- or parallelogram-shaped minute servo elements 13a˜13d representing servo data, such as preamble, address, burst data, etc., associated to the track T1. The servo pattern, which contains, for example, preamble, address and burst data associated with the individual tracks, comprises a plurality of rows of servo elements. Some of the servo elements 13b for burst data are displaced by a half track width in the radial direction so as to straddle a boundary between adjacent tracks. On the other hand, the groove patterns are concentrically configured to extend along the tracks, respectively, so as to separate them from one another. Each groove pattern comprises a continuous row of groove elements forming an inter-track groove. The discrete track medium to which the micro-pattern of the servo patterns and the groove patterns is finally transferred is of a type having land tracks and a recessed micro-pattern.

Each servo element 13a˜13d extends in a direction perpendicularly across the track T1 and has a radial length equal to a radial width of the track T1 and a width in the track direction greater than an irradiation spot diameter of an electron beam used in electron beam lithography. The servo elements 13b for the burst data are so displaced by a half track width in the radial direction that they straddle a boundary between adjacent tracks T1 and T2. In the data area 15 adjacent to the servo area 12 associated to the track T1 there is depicted an inter-track groove 16₁ divided into a plurality of groove elements 16a1˜16an in a continuous row at regular angles in the circumferential direction. The inter-track groove 16 separates the track T1 from the adjacent track T2. As described in detail later, when developing and etching the resist layer 11 of the disc substrate 10 with the micro-pattern comprising the servo pattern and the groove pattern formed as a latent image in the resist layer 11, the disc substrate 10 is provided with a topographical micro-pattern of servo elements and grove elements in the form of elevations.

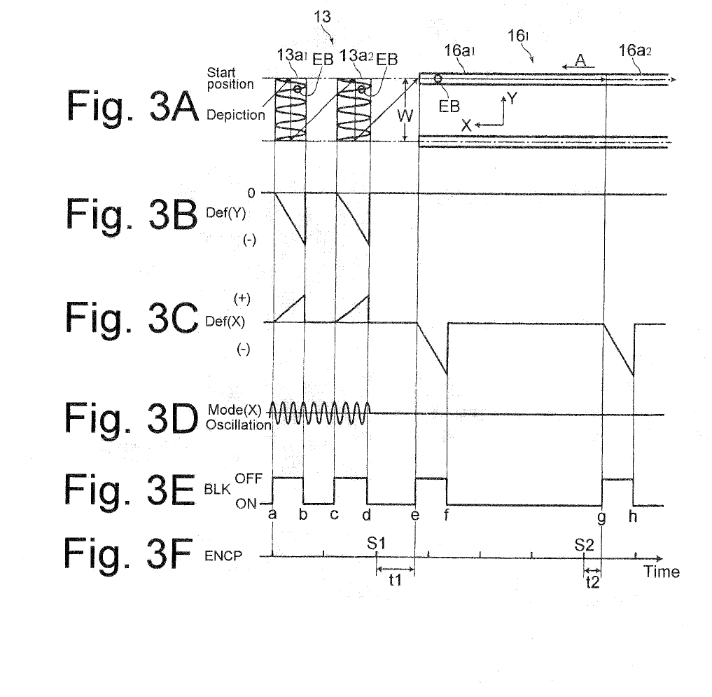

FIG. 3A illustrates, in schematic, simplified view, basic electron beam lithography of servo elements and a continuous row of groove elements. FIGS. 3B to 3F illustrate, in chart, electron beam control signals for depicting the servo elements and the groove elements by the electron beam lithographic method and system of the present invention. According to a basic aspect of the electron beam lithographic method and system of the present invention, the servo elements 13a1 and 13a2 and the inter-track groove elements 16a1, 16a2, . . . are sequentially depicted in order at predetermined phase positions of the concentric, but microscopically linear, track T1, for a full circle of each track during one revolution of the disc substrate 10. The electron beam lithography of servo elements and groove elements is performed by scanning the resist layer 11 of the disc substrate 10 with an electron beam EB having an irradiation spot diameter smaller than the width of the servo element 13a1, 13a2. The electron beam EB is driven to cause reciprocating micro-motion or oscillation at a fixed amplitude equal to the width of the servo element in the track direction X(+) identical with the rotative direction A of the disc substrate 10 during depiction of the servo elements 13a1, 13a2. Specifically, while scanning the resist layer 11 of the disc substrate 10 with the oscillating electron beam EB during rotation of the disc substrate 10 in one direction A, the electron beam EB is deflected at a speed according to a rotational speed of the disc substrate 10 by a distance equal to a track width W (which is a full radial length of the servo element) from a predetermined start position of scanning in the counter radial direction Y(−) and, at the same time, deflected at the same speed as the rotational speed of the disc substrate 10 in the track direction X(+), just the same direction as the rotative direction A of the disc substrate 10, perpendicular to the radial direction Y(+), for prevention of an occurrence of relative displacement between the irradiation spot of the electron beam EB and the disc substrate 10 in the track direction X(+) so as thereby to fill in or daub a full length of a rectangular shape of the servo element 13a1. In the same manner, the electron beam EB is deflected in the in both counter radial direction Y(−) and track direction X(+) simultaneously to daub a full length of a rectangular shape of the servo element 13a2. When daubing a shape of the servo element 13b or 13c (see FIG. 2) displaced by a half track width in the radial direction Y(+) or the counter radial direction Y(−), the electron beam EB is shifted in its start position of scanning by a half track width in the radial direction Y or the counter radial direction Y(−).

Subsequently to the sequential lithography of the servo elements 13a and 13a2, the electron beam EB linearly scans the resist layer 11 to depict the inter-track groove 16₁. Specifically, the electron beam EB is repeatedly deflected from the start position of scanning only in a counter track direction X(−) at regular intervals while the disc substrate 10 rotates at a constant angular velocity in the rotative direction A (identical with the track direction X(+)), so as thereby to fill in or daub shapes of the groove elements 16a1, 16a2, . . . without discontinuities among them so as thereby to depict the inter-track groove 16₁. It is noted that the electron beam EB is controlled to suspend its high-speed reciprocating micro-motion during depiction of the inter-track groove 16₁.

Greater details of the lithography of the servo elements and the groove elements are described below with reference to FIGS. 3(A) to 3(F). FIG. 3(A) illustrates, in schematic chart, the motion of the electron beam EB for the lithograph of the servo elements and the groove elements. FIG. 3(B) is a chart showing a deflection signal Def(Y) for deflecting the electron beam EB in a counter radial direction Y(−). FIG. 3(C) is a chart showing a deflection signal Def(X) for deflecting the electron beam EB in the track direction X(+) and the counter track direction X(−). FIG. 3(D) is a chart showing an excitation signal Mod(X) for causing a high-speed reciprocating micro-motion of the electron beam EB in the track direction X. FIG. 3(E) is a chart showing a blanking (BLK) signal for intermittently blanking and un-blanking the electron beam EB. FIG. 3(F) is a chart showing an encoder pulse signal ENCP for synchronizing depiction of the groove elements with the electron beam EB with rotation of the disc substrate 10.

Upon a start of the electron beam lithography at a point of time “a,” a BLK signal turns into a blanking-OFF condition (un-blanking condition) to un-blank or commence irradiation of the electron beam EB to the resist-layer 11 of the rotating disc substrate 10 at the reference position. Simultaneously, lithographic data signals including an excitation signal Mod(X), a track direction deflection signal Def(Y), a radial direction deflection signal Def(X) and an encoder pulse signal ENCP are provided Then, the electron beam EB causes a high-speed reciprocating micro-motion in the track direction X at a fixed amplitude according to the excitation signal Mod(X) and is, at approximately the same time, deflected at a speed according to a rotational speed of the disc substrate 11 in the counter radial direction Y(−) according to the deflection signal Def(Y) and in the track direction X(+) at a speed equal to the rotational speed of the disc substrate 10 according to the deflection signal Def(X). The deflection of the electron beam EB in the track direction X(+), just the same direction as the rotative direction A of the disc substrate 10, prevents an occurrence of relative displacement between the disc substrate 10 and the electron beam EB in the track direction X(+). At a point of time “b,” the BLK signal turns into a blanking-ON condition (blanking condition) to blank or shut irradiation of the electron beam EB and, at the same time, the deflection signals Def(Y) and Def(X) disappear to deflect back the electron beam EB to the reference position. In this way, the servo element 13a is daubed in a distortion-free rectangular shape. At a point of time “c” after a lapse of a regular interval, the BLK signal turns into the blanking-OFF condition to perform depiction of the servo element 13b in just the same manner as described above and, at a point of time “d,” turns into the blanking-ON condition. When depiction of the servo elements 13a1 and 13a2 is completed, the control signals, i.e. the excitation signal Mod(X), the track direction deflection signal Def(Y) and the radial direction deflection signal Def(X), are disappeared once although the disc substrate 10 continues to rotate.

Subsequently, after a lapse of a specified interval, the BLK signal intermittently turns into the blanking-OFF condition at a point of time “e” and the blanking-ON condition at a point of time “f” at regular intervals. Every time the BLK signal turns into the blanking-OFF condition, a track direction deflection signal Def(X) is provided to deflect the electron beam EB in the counter track direction X(−). The deflection signal Def(X) disappears once at a pint of time “f” to return the electron beam EB to the reference position and to be blanked, thereby completing depiction of a specified length of groove element 16a. The length of the groove element is the total distance of a rotated distance of the disc substrate 10 in the track direction X(+) and a deflected distance of the electron beam EB in the counter track direction X(−) for the period of time between the points of time “e” and “f”. Since there is not provided any deflection signal Def(Y) after the point of time “d,” the electron beam EB linearly scans the resist-layer 11 of the rotating disc substrate 10 to daub a straight line a width substantially equal to the irradiation spot diameter of the electron beam EB for the groove element 16a. Since, even though the groove element is straight, it is nevertheless extremely short in length, the groove element is not accompanied by a measurable deviation from the circular-arcuate inter-track.

When the disc substrate 10 attains rotational movement equal to the specified length of groove element 16a1 at a point of time “g,” in other words, after a lapse of the regular interval, the BLK signal turns into the blanking-ON condition. In the same manner as described in connection with the groove element 16a1, the electron beam EB is deflected to depict the specified length of groove element 16a2 while the BLK signal remains in the blanking-OFF condition between points of time “g” and “h.” In this way, the groove elements 16a1, 16a2, . . . are depicted in a continuous strait row to form an unbroken inter-track groove 16₁.

The specified length of groove element 16a1, 16a2, . . . is determined corresponding to the intensity of the high-speed oscillatory electron beam EB which has been determined so as to provide an irradiation dose sufficiently enough to make proper irradiation of the electron beam EB to the resist layer 11. That is, the electron beam EB has the peculiarity that it makes irradiation of a width (the effective width of irradiation) which is apt to become greater than the irradiation spot diameter depending on an irradiation time. Accordingly, in order to depict an intended width of groove element, the electron beam EB is deflected in the counter track direction X(−) at a controlled deflection speed so as to provide an irradiation dose properly satisfying the intended width of groove element. Specifically, the electron beam EB is deflected at a higher deflection speed so as to reduce the irradiation dose per unit area for a thin groove element and, on the other hand, at a lower deflection speed so as to increase the irradiation dose per unit area for a thick groove element It is noted that it is difficult to change the intensity of electron beam during execution of the electron beam lithography of an inter-track groove in terms of responsibility of the electron beam to rotation of the disc substrate 10.

Upon performing the electron beam lithography of groove elements, it is preferred to determine precise start points of depiction of the groove elements 16a, 16b, . . . , namely the points of time “e”, “g”, . . . , based on encoder pulse signals S1, S2, . . . as shown in FIG. 3(F) so as thereby to terminate the depiction of the groove elements 16a1, 16a2, . . . at a precise position of a boundary of the data area. Specifically, the BLK signal and the counter track direction deflection signal Def(X) are synchronized with the encoder pulse signals S1 and S2 so as to commence irradiation of the electron beam EB at the points of time “e” and “g” after lapses of predetermine times t1 and t2 from generation of the encoder pulse signals S1 and S2, respectively.

When achieving the electron beam lithography of servo elements and groove elements for a full circle of the outermost track during one revolution of the disc substrate 10, after moving the electron beam EB by a distance equal to the track width W in the counter radial direction Y(−) or the disc substrate 10 by the distance in the radial direction Y(+), the same steps are repeated to perform the electron beam lithography of servo elements and groove elements for a full circle of the following track. When achieving the electron beam lithography of servo elements and groove elements for full circles of all tracks, all sectors of the disc substrate 10 are provided with the same servo patterns 13 and the groove patterns 16.

It is preferred that the disc substrate 10 is controlled to rotate at a speed increasing gradually from depiction of a row of servo elements and a continuous row of groove elements for the outermost track to that for the innermost track so as to keep the same linear velocity of scanning allover the resist-layer 11, thereby depicting the servo elements and the groove elements with an uniform electron beam irradiation and securing precise locations of the servo elements and the groove elements.

If the electron beam EB has a movable distance in the radial direction Y several times the track width, the disc substrate 10 is moved by a radial distance several time the track width every time the electron beam lithography of servo elements and groove elements is continuously performed for full circles of several tracks.

Scanning with the electron beam EB for the electron beam lithography of the servo pattern 13 and the groove pattern 16 is controlled by lithographic data signals controlled in timing and phase based on encoder pulse signals provided corresponding to rotation of the disc substrate and a reference clock signal.

In the case where the lithography of the servo pattern 13 and the groove pattern 16 is performed in a constant angular velocity (CAV) system, distances of the servo element and the groove element are varied gradually short between the outermost track and the innermost track corresponding to a change in sector length in the track direction X. In this instance, while depicting a servo element, the electron beam EB is deflected in the counter radial direction Y(−) at a speed higher at an inner track than at an outer track. In other words, the electron beam EB is deflected at a speed gradually declining with an increase in the distance of the reference point from the center of rotation of the disc substrate 10 so as to make a irradiation dose of electron beam per unit area uniform for the servo elements 13a˜13d and the groove elements 16a1, 16a2, . . . . As a result, exposure of the servo elements and the groove elements is uniformly made in the same stable state that the electron beam EB oscillates at a fixed amplitude and is fixed in intensity. It is noted that the electron beam EB is deflected in the track direction X(+) or the counter track direction X(−) at a speed fixed despite of track locations but by a distance in the track direction X(+) or X(−) adjusted depending on track locations, so as thereby to vary the length of element in the track direction.

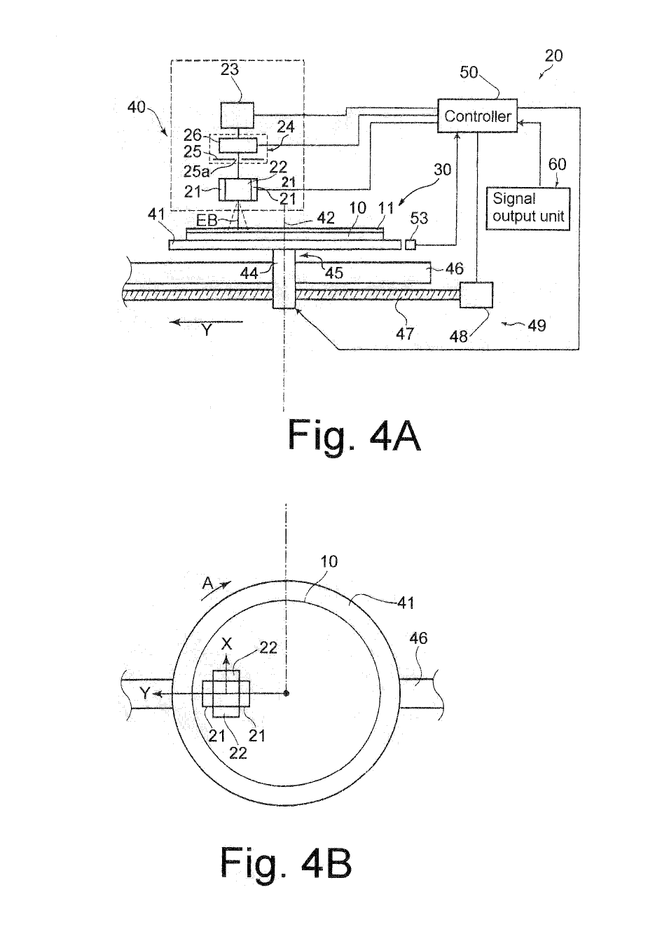

FIG. 4 is a schematic illustration showing an electron beam lithographic system 20 which is used to perform the electron beam lithography as described above. This electron beam lithographic system 20 includes an electron beam lithographic apparatus 40, a linearly movable rotating stage device 30, a signal output unit 60 and a controller 50.

The electron beam lithographic apparatus 40 comprises an electron gun 23, deflection means 21 and 22, and blanking means 24. The electron gun 23 emits the electron beam EB. The deflection means 21 and 22 deflects the electron beam EB in the radial direction Y and the track direction X, respectively, and causes reciprocating micro-motion in the track direction X at a fixed amplitude. The blanking means 24, which allows and interrupts irradiation of the electron beam EB, comprises an aperture mask 25 having a center aperture 25a and deflection means 26 for deflecting the electron beam EB according to BLK signals. The blanking means 24 is so configured that the deflection means 26 does not act on the electron beam EB so as to allow irradiation of the electron beam EB through the center aperture 25a of the aperture mask 25 while the BLK signal remains in the blanking-OFF condition and, however, deflects the electron beam EB so as to interrupt irradiation of the electron beam EB by the aperture mask 25 while the BLK signal remains in the blanking-ON condition. The electron beam EB emanating from the electron gun 23 and passing through the center aperture 25a of the aperture mask 25 is irradiated onto the resist-layer 11 of the disc substrate 10 through the deflection means 21 and 22 and an focusing lens system (not shown) so as thereby to scan the resist-layer 11 of the disc substrate 10 for depicting shapes of the servo elements and groove elements.

The linearly movable rotating stage device 30 includes a rotating stage unit 45 for supporting the disc substrate 10 thereon for rotation and a linear driving device 49 for driving the rotating stage unit 45 for linear movement in a direction perpendicular to an axis of rotation. The rotating stage unit 45 comprises a stage 41 on which the disc substrate 10 is put and a spindle motor 44 for rotating the stage 41 about a center axis 42 of the stage 41. The linear driving device 49 comprises a guide rod 46 supporting the rotating stage unit 45 for linear slide movement in the direction perpendicular to the center axis 42 of the rotating stage 41, a precise threaded shaft 47 screwed in a portion of the spindle motor 44 and extending in parallel with the guide rod 46, and a reversible pulse motor 48 connected to the threaded shaft 47. The pulse motor 44 is pulse controlled to turn the threaded shaft 47 in opposite directions so as thereby to shift a position of the rotating stage unit 45 along the guide rod 46. There is further provided an encoder 53 which generates an encoder pulse signal every time it detects a regular angular rotation of the stage 41 The encoder pulse signal is sent to the controller 50.

The signal output unit 60 stores lithographic data for representing the micro-pattern comprising the servo patterns and the inter-track groove patterns to be depicted on the resist-layer of the disc substrate 10 and sends the lithographic data to the controller 50. The controller 50 has a self-contained clock means for generating a reference clock pulse for the timing control described above. Based on the lithographic data, the controller 50 provides control signals for controlling the coordinated operation of the electron beam lithographic apparatus 40 and the linearly movable rotating stage device 30 as described above, thereby performing the electron beam lithography of the micro-pattern comprising the servo patterns and the inter-track groove patterns on the resist-layer 1 of the disc substrate 10. It is preferred to adjust an intensity and an irradiation spot diameter of the electron beam EB in consideration of the shape of individual element and sensitivity of the resist layer 11.

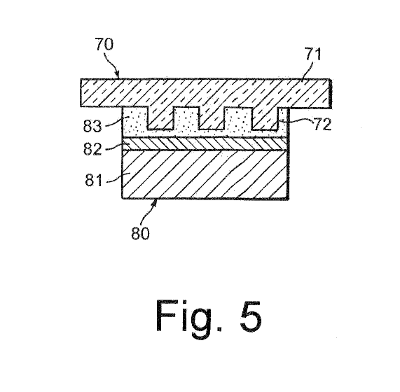

The disc substrate 10 with the micro-pattern depicted as a latent image by the electron beam lithography method and system is completed by development and etching the resist layer 11 so that the surface of the disc substrate 11 is topographically configured in a recessed micro-pattern. The disc substrate 10 thus prepared is used as an imprint mold 70 as shown in FIG. 5.

FIG. 5 illustrates an imprint process of transferring the micro-pattern of the master imprint mold 70 to a slave medium 80. The imprint mold 70, provided as the disc substrate 10, comprises a transparent disc substrate 71 having a micro-patterned surface 72 in the form of land configuration. The slave medium 80 comprises a disc substrate 81 with a magnetic layer 82 coated thereon and covered by an ultraviolet curable type of resin resist layer 83. The imprint mold 70 is so pressed against the slave medium 80 that the micro-patterned surface 72 is dug into the resin resist layer 83. Then the resin resist layer 83 is exposed to ultraviolet rays through the translucent disc substrate 71 so as thereby to solidify exposed parts of the resist resin layer 83. When removing the imprint mold 70 from the slave medium 80 and then etching the resin resist layer 83, the micro-pattern of the imprint mold 70 is transferred in a negative form (a pattern of openings) into the resin resist layer 83. Thereafter, when etching the magnetic layer 82 of the slave medium 80 using the micro-patterned resist layer 83 as a mask, the micro-pattern is formed in the form of recessed pattern in the magnetic layer 82 of the slave medium. In this way, the slave medium 80 is completed as a discrete track medium.

It is also to be understood that although the present invention has been described with regard to preferred embodiments thereof, various other embodiments and variants may occur to those skilled in the art, which are within the scope and spirit of the invention, and such other embodiments and variants are intended to be closed by the following claims.

What is claimed is:

1. An electron beam lithographic method for forming an image of a micro-pattern on a resist-coated surface of a disc substrate by scanning the resist-coated surface of said disc substrate with an electron beam during rotation of the disc substrate, said micro-pattern, which is desirably to be topographically formed in each of concentric tracks of a discrete track recording medium, comprising a servo pattern which comprises a plurality of recessed servo elements having specified regular widths in a direction of said track and a groove pattern which comprises an inter-track groove extending along said track so as to magnetically isolate said track from adjacent tracks, said electron beam lithographic method comprising the steps of:
forming said servo elements as a latent image in sad resist-coated surface of said disc substrate with an electron beam having an irradiation spot diameter smaller than said width of said servo element during rotation of said disc substrate in one rotative direction; and
forming, subsequently to formation of said servo elements, said inter-track groove as a latent image in sad resist-coated surface of said disc substrate by linearly scanning said resist-coated surface of said disc substrate in a direction perpendicular to a radial direction of said disc substrate at regular intervals during said rotation of said disc substrate so as thereby to form a continuous row of groove elements into which said inter-track groove is divided.

2. The electron beam lithographic method as defined in claim 1, wherein said electron beam is deflected in said radial direction while oscillated at a specified frequency in a direction perpendicular to said radial direction so as to daub a shape of each said servo element during said rotation of said disc substrate, thereby forming said servo element as a latent image in sad resist-coated surface of said disc substrate.

3. The electron beam lithographic method as defined in claim 1, wherein said electron beam is intermittently deflected in a direction perpendicular to said radial direction and opposite to the rotative direction of the disc substrate during the rotation of the disc substrate so as to daub the individual groove elements, thereby depicting a continuous line having a length of the groove element on the resist-coated surface of the disc substrate.

4. The electron beam lithographic method as defined in claim 1, and further providing an encoder pulse for enabling irradiation of said electron beam to said resist-coated surface of said disc substrate immediately before formation of each said groove element.

5. An electron beam lithographic system for forming a micro-pattern as a latent image in a resist-coated surface of a disc substrate by scanning the resist-coated surface of said disc substrate with an electron beam while rotating the disc substrate, said micro-pattern, which is desirably to be topographically formed in each of concentric tracks of a discrete track recording medium, comprising a servo pattern which comprises a plurality of recessed servo elements having specified regular widths in a direction of said track and a groove pattern which comprises an inter-track groove extending along said track so as to magnetically isolate said track from adjacent tracks, said electron beam lithographic system comprising:
a signal output unit for storing lithographic data representing said micro-pattern and providing signals corresponding to said lithographic data; and
an electron beam lithographic apparatus operative according to said signals to perform the steps of forming said servo elements as latent images in sad resist-coated surface of said disc substrate with an electron beam having an irradiation spot diameter smaller than said width of said servo element during rotation of said disc substrate in one rotative direction and forming, subsequently to formation of said servo elements, said inter-track groove as a latent image in sad resist-coated surface of said disc substrate by linearly scanning said resist-coated surface of said disc substrate in a direction perpendicular to a radial direction of said disc substrate at regular intervals during said rotation of said disc substrate so as thereby to form an image of a continuous row of groove elements into which said inter-track groove is divided.

6. The electron beam lithographic method as defined in claim 5, wherein said electron beam is deflected in said radial direction while oscillated at a specified frequency in a direction perpendicular to said radial direction so as to daub a shape of each said servo element during said rotation of said disc substrate, thereby forming said servo element as a latent image in sad resist-coated surface of said disc substrate.

7. The electron beam lithographic method as defined in claim 5, wherein said electron beam is deflected in a direction perpendicular to said radial direction and opposite to said rotative direction of said disc substrate by a distance during said rotation of said disc substrate so as to daub a line having a length equal to a length of said groove element, thereby forming each said groove element as a latent image in in said resist-coated surface of said disc substrate.

8. The electron beam lithographic method as defined in claim 5, and further providing an encoder pulse for enabling irradiation of said electron beam onto said resist-coated surface of said disc substrate immediately before formation of each said groove element.

9. An electron beam lithographic system as defined in claim 5, wherein said electron beam lithographic apparatus comprises:
a rotating stage for bearing said disc substrate thereon;
drive means for rotating said rotating stage in one rotative direction and linearly moving said rotating stage in a direction perpendicular to said rotative direction;
an electron gun for emitting an electron beam;
deflection and oscillation means for deflecting said electron beam in said radial direction of said disc substrate put on said rotating stage and in a direction perpendicular to said radial direction of said disc substrate and opposite to said rotative direction of said rotating stage and causing a high speed oscillation of said electron beam in a direction perpendicular to said radial direction at a fixed amplitude;
blanking means for blanking irradiation of said electron beam onto said resist-coated surface of said disc substrate after formation of each said servo element and each said groove element;
a controller for controlling coordinated operation of said drive means, said electron gun, said deflection and oscillation means and blanking means so as to perform formation of said micro-pattern according to said signals corresponding to said lithographic data provided by said signal output unit.

10. A disc substrate bearing a micro-pattern to be transformed onto a discrete track medium, said micro-pattern being formed by developing and etching said resist-coated surface of said disc substrate with said micro-pattern formed as a latent image therein by said electron beam lithographic method as defined in claim 1.
